(19) United States
(12) Patent Application Publication
(10) Pub. No.: US 2026/0162930 A1
(43) Pub. Date: Jun. 11, 2026

(54) TILT MEASUREMENT IN PARTICLE MICROSCOPE SYSTEMS

(71) Applicant: Carl Zeiss SMT GmbH, Oberkochen (DE)

(72) Inventor: Florian HUBER, Aalen (DE)

(21) Appl. No.: 19/461,229

(22) Filed: Jan. 27, 2026

Related U.S. Application Data
(63) Continuation of application No. PCT/EP2024/070856, filed on Jul. 23, 2024.

(30) Foreign Application Priority Data
Aug. 4, 2023 (DE) 10 2023 120 736.9

(51) Int. Cl. H01J 37/244; H01J 37/28

(52) U.S. Cl. CPC H01J 37/244; H01J 37/28; H01J 2237/24578; H01J 2237/2482; H01J 2237/31749

(57) ABSTRACT

A particle microscope system comprises: a vacuum chamber; a sample holder having a holding surface which extends in a plane of the vacuum chamber and on which a sample can be arranged; a source column disposed in the vacuum chamber and configured to shape and scan a primary particle beam; a laser light source configured to emit laser light towards the holding surface along a beam path; and an autocollimator detection system arranged in the beam path downstream of the holding surface in a propagation direction of the laser light. The autocollimator is configured to output a signal which is selectively sensitive to a tilt of a reflector in the beam path at the holding surface. A projection of the beam path on the holding surface defines a measurement region. A central axis of the source column intersects the measurement region.

### CROSS-REFERENCE TO RELATED APPLICATIONS

The present application is a continuation of, and claims benefit under 35 USC 120 to, international application No. PCT/EP2024/070856, filed Jul. 23, 2024, which claims benefit under 35 USC 119 of German Application No. 10 2023 120 736.9, filed Aug. 4, 2023. The entire disclosure of each of these applications is incorporated by reference herein.

### FIELD

Various examples of the disclosure relate to the measurement of the tilt and/or height of a sample to be examined in the case of particle microscope systems, such as electron beam microscopes having an additional column for creating a focused ion beam.

### BACKGROUND

In the case of electron beam microscopes (scanning electron microscopes; SEMs), a sample is arranged on a holding surface of a sample holder (also referred to as sample stage). Some applications have the ability to make quantitative statements about the arrangement or geometry of specific structures in the SEM images. This typically involves determining the relative arrangement of the sample in a reference coordinate system. For example, this can include a possible tilt of the sample with respect to the holding surface. For example, there is a desire for techniques that render determinable the tilt of a wafer relative to the particle beam.

It is known that a measurement of the arrangement of a sample in an SEM can comprise capacitive height sensors, optical height sensors and interferometer-based pose determination.

Capacitive sensors, for example capacitive sensors for path, distance and position, are generally operated in an “on-axis” configuration, but this may not allow a direct measurement below the SEM objective. Moreover, capacitive height sensors usually do not allow direct measurement of the tilt. Typically, the latter can only be calculated by way of a plurality of instruments or measurement points. A disadvantage of these the capacitive height sensors can be electromagnetic interference in the SEM column due to the electronics of the height sensor.

Optical height sensors, especially white light interferometers for measuring absolute distance with sub-nanometre resolution, are known for their high measurement accuracy down to sub-nanometre levels. They also use an “on-axis” configuration, which can prevent the direct measurement below the SEM objective. Like capacitive sensors, they generally do not allow a direct measurement of the tilt. Typically, the latter can only be calculated by way of the indirect route of a plurality of instruments or a plurality of measurement points. While this method can allow a relatively precise measurement, it can be relatively complicated and slow in implementation.

Both of the aforementioned methods are generally applied “on axis” and hence perpendicular to the wafer surface, meaning that a direct measurement of the wafer surface below the SEM objective proves impossible. As a result, in general, there always is a lateral offset between the optical/capacitive measurement and SEM measurement point. Thus, these sensors are usually installed relatively close to the SEM objective in order to be able to perform measurements with the smallest reasonably possible lateral offset from the scan region in which the electron beam is raster-scanned. In addition to relatively limited installation space, electromagnetic interference in the SEM on account of the small distance of the component parts is generally undesirable in these measurement methods. Moreover, a direct measurement of the tilt of the sample surface can prove impossible in the case of pure height sensors such as capacitive measurement methods, for example. Instead, a plurality of measurement points can be recorded at different locations followed by determination of the angular pose of the wafer therefrom.

This can increase the measurement duration and can reduce the measurement accuracy in comparison with a direct “single-shot” measurement.

Alternatively, the focal position at a plurality of points on the sample surface, and hence the alignment of the surface, can be determined directly via SEM. Since a plurality of measurement points are used to determine the pose and both stigmatism and focus are usually optimized at each point, this method can be relatively time-consuming and, moreover, generally cannot be performed in parallel with the actual measurement function of the SEM. Moreover, the accuracy generally depends on the depth of field of the SEM and hence on the working point of the equipment. An SEM-independent and direct measurement method for determining the sample surface pose is relatively desirable in this context.

### SUMMARY

The disclosure seeks to provide improved techniques for measuring the arrangement of sample objects in particle microscope systems.

In an aspect, the disclosure provides a particle microscope system, comprising: a vacuum chamber; a sample holder having a holding surface which extends in a plane of the vacuum chamber and on which a sample can be arranged; a source column disposed in the vacuum chamber and configured to shape and scan a primary particle beam; a laser light source configured to emit laser light towards the holding surface along a beam path; and an autocollimator detection system arranged in the beam path downstream of the holding surface in a propagation direction of the laser light and configured to output a signal which is selectively sensitive to a tilt of a reflector in the beam path at the holding surface. A projection of the beam path on the holding surface defines a measurement region. A central axis of the source column intersects the measurement region.

In an aspect, the disclosure provides a method for determining an arrangement of a sample in a particle microscope system. The method comprises: arranging the sample on a holding surface of a sample holder of the particle microscope system; positioning the sample holder in a vacuum chamber of the particle microscope system such that the sample is arranged below a source column of the particle microscope system; controlling a laser light source such that the laser light source emits laser light towards a holding surface along a beam path such that the laser light is reflected at the sample below the microscope objective; and controlling an autocollimator detection system arranged in the beam path downstream of the sample in the propagation direction of the laser light, in order to obtain a signal which is selectively sensitive to a tilt of the sample.

### BRIEF DESCRIPTION OF THE FIGURES

FIG. 1 schematically illustrates a particle microscope system having an optical autocollimator detection system according to various examples.

FIG. 2 schematically illustrates a particle microscope system having an optical autocollimator detection system and a further optical detection system, in order to measure both a tilt and a height of a sample on a sample holder according to various examples.

FIG. 3 schematically illustrates the measurement principles of the two optical detection systems from FIG. 2 according to various examples.

FIG. 4 illustrates various configurations for the further optical detection system according to various examples.

FIG. 5 schematically illustrates a capacitive sensor for measuring a height and tilt of a sample according to the prior art.

FIG. 6 schematically illustrates the integration of an optical measurement according to various examples in a particle microscope system comprising an SEM and a focused ion beam arrangement.

FIG. 7 schematically illustrates the integration of an optical measurement according to various examples in a particle microscope system comprising an SEM and a focused ion beam arrangement.

FIG. 8 schematically illustrates the integration of an optical measurement according to various examples in a particle microscope system comprising an SEM and a focused ion beam arrangement.

### DETAILED DESCRIPTION

Techniques which allow determination of an arrangement of a sample in a reference coordinate system of a particle microscopy system are disclosed below. For example, it is possible to determine a tilt of the sample in the reference coordinate system and/or a height of the sample in the reference coordinate system (also referred to as Z-position). Thus, the reference coordinate system can be a machine coordinate system, in relation to which a sample holder of the particle microscopy system is positionable and microscopy or manipulation via particles is possible. For example, imaging via a raster-scanned electron beam can be performed in an SEM microscopy system, wherein the image plane is defined in relation to the reference coordinate system.

For example, techniques are disclosed below in the context of an SEM microscopy system. However, corresponding techniques can be used for different particle microscopy systems because these have comparable structures (vacuum chamber with a source column and a detector column, for forming a primary particle beam and for detecting secondary particles). For example, the techniques described herein can also find use in a particle microscopy system having a plurality of source columns in a crossed arrangement, i.e. for example in a particle microscopy system with SEM imaging and manipulations via a focused ion beam (FIB).

The techniques described herein for determining an arrangement of the sample in the particle microscope system can be used for various applications. For example, it is possible to determine the tilt of a surface of the sample with respect to a reference coordinate system of the sample holder or particle microscope system. It is then possible to make quantitative statements about the alignment of specific structures of the sample object because the alignment of the primary particle beam in relation to the reference coordinate system is also known.

For example, the 3-D tomography method is applied in the semiconductor industry for wafer inspection purposes. In this case, very thin layers of the semiconductor material are ablated within a region of interest (ROI) via a focused ion beam, and high-resolution images of each layer are recorded by SEM. The image stack thus created is reconstructed in digital postprocessing, and hence a 3-D image of the examined volume is created. To be able to exactly determine the pose of the examined volume relative to the wafer surface and the relative alignment of a plurality of ROIs with respect to one another on a wafer, it is desirable to exactly measure the local tilt of the wafer surface and height variations.

However, use of the tilt of the sample in the evaluation of the SEM microscope images is only one possible application in this context. In an alternative to that or in addition, use the tilt of the sample during the measurement would also be conceivable, for example by virtue of actuators of the sample holder being driven such that the tilt is compensated.

What can be achieved as a result is that the sample—a wafer, for example—adopts a specific pose in the reference coordinate system.

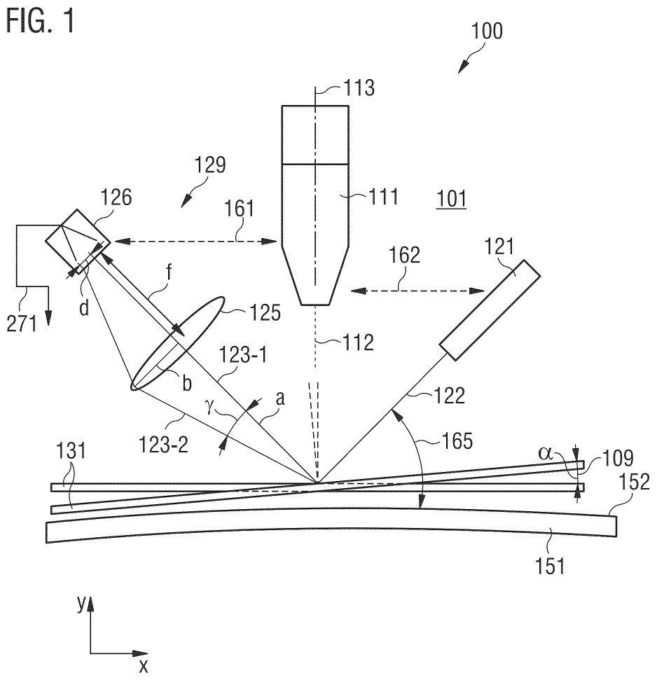

FIG. 1 schematically illustrates a particle microscope system 100. For example, FIG. 1 illustrates an SEM having a source column 111 configured to shape and scan a primary particle beam 112. The source column thus comprises an objective. The primary electron beam 112 is raster-scanned over a sample 131 in a specific region (scan region).

Typically, the lateral extent of the scan region is of the order of 50 μm×50 μm or smaller. FIG. 1 also shows a central axis 113 of the source column 111, the central axis typically being arranged centrally in the scan region. The SEM 100 also comprises a detector, which is not shown in FIG. 1. The detector detects secondary particles created by the primary electron beam and/or backscattered primary electrons. The detector is typically arranged at a distance from the source column. An Everhart-Thornley detector (scintillator+photomultiplier) is often installed; a positive voltage is applied thereto and accelerates the emerging electrons in the direction of the detector.

The source column 111 is arranged in a vacuum chamber 101 together with a sample holder 151, on the holding surface 152 of which the sample 131—a wafer in the example of FIG. 1—is placed. In the illustrated example, the source column 111 is arranged perpendicular to a holding surface 152 of the sample holder 151; i.e. the source column 111 is at a polar angle of approximately 90° in a corresponding spherical coordinate reference system whose XY-plane (equatorial plane) is on the holding surface 152 and which is centred on a central axis 113 of the source column 111 (in any case in the zero position of the holding surface 152 if the sample holder 151 should also be tiltable).

In the example of FIG. 1, the wafer 131 is depicted in two states with different tilts. For example, a tilt of the wafer 131 vis-à-vis the sample holder 151 or xy-plane of the reference coordinate system may be caused by mechanical tolerances or by wafer bow.

The particle microscope system 100 further comprises a laser light source 121. The laser light source 121 is configured to emit laser light towards the sample holder 151 along a beam path 122. The angle of incidence 165 is tilted, and the measurement is not an “on-axis” measurement.

For example, the laser light source 121 can be a laser or a laser diode which is guided via an optical fibre to the relative position in relation to the sample holder 151 shown in FIG. 1. Then the light can be output coupled from the optical fibre and collimated. To this end, a lens serving to bring about collimation can be attached to the end of the optical fibre.

The collimated laser light then propagates along the beam path 122 with a comparatively small divergence. This means that the cross section of the beam path 122 does not change or does not change substantially as a function of position along the beam path.

In the illustrated example of FIG. 1, the wafer 131 is arranged on the sample surface 152 and therefore acts as a reflector for the laser light. The holding surface 152 itself acts as a reflector when no sample is arranged on the sample holder 151.

Different beam paths 123-1, 123-2 of the reflected laser light arise post reflection on the reflector, depending on the tilt 109. This dependence of the beam paths 123-1, 123-2 on the tilt 109 is exploited for the purpose of measuring the tilt. To this end, the SEM 100 comprises an autocollimator detection system 129. The latter comprises a focusing lens 125 and a multi-pixel sensor 126 comprising a sensor surface 127. The example in schematic FIG. 1 shows that the beam paths 123-1, 123-2 (which correspond to different tilts) are incident at different positions on the sensor surface on account of the different angles of incidence. Thus the position of the laser light on the sensor depends on the tilt of the reflector in the beam path. The detection system 129 therefore operates according to the autocollimator principle. To this end, the cross section of the beam path is substantially smaller than the aperture of the focusing lens 125 to ensure that the latter is not illuminated over a large area or that illumination does not extend therebeyond. What this achieves is that different tilts are imaged on different pixels of the sensor surface 127 (for example, a CMOS or CCD sensor can be used). Thus the focusing lens 125—a convex lens in this case—is used to focus the light reflected by the reflector—for example, the wafer surface in this case—on the sensor surface 127. In this case, the position of the focal point on the sensor surface 127 is independent of the lateral position of the incident light but sensitive to the change in angle, i.e. also sensitive to a change in the tilt of the sample to be examined. Thus the autocollimator detection system 129 is configured to focus the laser light on the multi-pixel sensor 126 such that the position of the light spot on a sensor surface 127 of the multi-pixel sensor 126 changes with a tilt of the reflector in the beam path 123, 123-1, 123-2.

Depending on the focal length f of the focusing lens 25 there is a displacement d of the signal on the sensor surface 127, caused by a tilt 109 of the reflector a over d=2f·tan(a).

In this case, the tilt 109—denoted here by a—may be defined in relation to a zero position in the reference coordinate system, i.e. the angle between the xy-plane of the reference spherical coordinate system and the wafer surface. The absolute pose of the signals of the detection system 129 with respect to the electron beam can be determined by a one-time calibration measurement via SEM. That is to say, the image plane of the SEM can be registered in the reference coordinate system. As a result, the measured angle data with respect to the tilt can be related directly to the SEM alignment, and mechanical tolerances do not influence the absolute accuracy. This therefore means that the SEM measurement and the measurement via the detection system 129 can both be related to the same reference coordinate system.

The sensor 126 thus provides a signal 271 which is indicative for the tilt 109 of the reflector in the beam path 122, 123-1, 123-2. For example, the signal is selectively sensitive to this tilt and for example is not influenced by different heights of the sample 131 for example.

As a result of measuring the tilt of the wafer 131 in the measurement regions directly below the source column 111 of the SEM, systematic errors on account of a distance between the measurement regions and the scan region, as occurs in reference implementations with for example a capacitive sensor, are avoided. Moreover, the techniques described herein do not require successive capture of a plurality of measurement points in order to then deduce the tilt on the basis of the plurality of measurement points. Instead, a single-shot measurement can be used to determine the tilt.

This also increases the accuracy because it is possible to manage without for example repositioning the sample between two measurement points, as occurs in reference implementations. Additionally, the measurement duration is reduced, ensuring a higher throughput (useful within the scope of in-line characterization for example).

The aperture of the focusing lens 125 and its distance from the reflector defines the acceptance angle of the autocollimator measuring system 129.

The acceptance angle can be suitably dimensioned depending on the desired application.

For example, the techniques described herein could be used for a particle microscope system 100 which is dimensioned for the large-area inspection of wafers (before these are broken into chips). This is particularly suitable for in-line characterization during a semiconductor manufacturing process. For example, 300 mm wafers can be inspected, for instance via 3-D tomography techniques. Small tilts are expected in such scenarios, for example of the order of <1000 μrad. Therefore, the expected tilt 109 is located within a limited angular range but should be determined with particularly high accuracy. It was established that an acceptance angle of +/−3° or less is suitable for such applications. For example, such an acceptance angle can be achieved using a focusing lens with an aperture of 1 inch, attached at a distance of 300 mm from the measurement regions. Using the arrangement in FIG. 1, it is possible to measure the tilt of the wafer 131 (in a single-shot measurement) directly below the source column 111. Thus this means that the projection of the beam path 122 of the laser light on the holding surface 152 of the sample holder 151 defines a measurement region for determining the tilt, and the central axis 113 of the source column 111 intersects the holding surface 152 in this measurement region. This can also be referred to as a crossed arrangement, in which the beam path 122 and the primary electron beam 112 intersect in the region of the sample (the wafer 131 in the example of FIG. 1) or holding surface 152.

For example, a cross section of the beam path 122 of the laser light may have a diameter of the order of 250 or 500 μm. Typically, the cross section of the beam path 122 of the laser light thus is larger than the scanning region of the SEM, i.e. larger than the image field. However, a collimation of the laser light to a cross section of the same order of magnitude as the size of the scan region would also be conceivable in some examples.

For example, the size of the scan region may lie in the range of 70-120% of the cross section of the beam path 122.

For example, there are wafers of different thickness. For example, there are wafers with a thickness of between 50 μm and 800 μm. Thus, the autocollimator detection system 129 is suitable for measuring a tilt 109 of the wafer independently of its thickness. A corresponding variation in the height of the sample might also arise due to the fact that different techniques are used for affixing the sample to the holding surface 152 of the sample holder 151. For example, adhesive pads with different thicknesses can be used. Furthermore, there might also be process-related height variations on the wafer surface. Moreover, the distance between SEM column 111 and sample surface may vary on account of mechanical tolerances. It is therefore useful if the autocollimator detection system is able to measure a change in the tilt 109 independently of the height of the sample.

Moreover, a large spatial distance 161, 162 is attainable between the component parts 121, 125, 126, 129 for measuring the tilt of the sample relative to component parts (for example the source column 111) of the SEM system. This prevents electromagnetic crosstalk or interference with the SEM measurement. All this is rendered possible by the oblique incidence of the beam path 122 (cf. angle of incidence 165 with respect to the holding surface 152).

The corresponding measuring method enables a particularly quick determination of the sample pose. For example, use can be made of a CMOS camera for the implementation of the sensor 126, or photodiodes/PSDs (position sensitive devices) which have sampling frequencies in the range of kilohertz or megahertz. For example, this would allow, within a short period of time, a large-area measurement of the tilt of the sample by way of a corresponding lateral repositioning of the sample by displacing the sample stage. Finally, the described techniques can also determine the tilt of the sample particularly accurately; this will still be discussed in detail below.

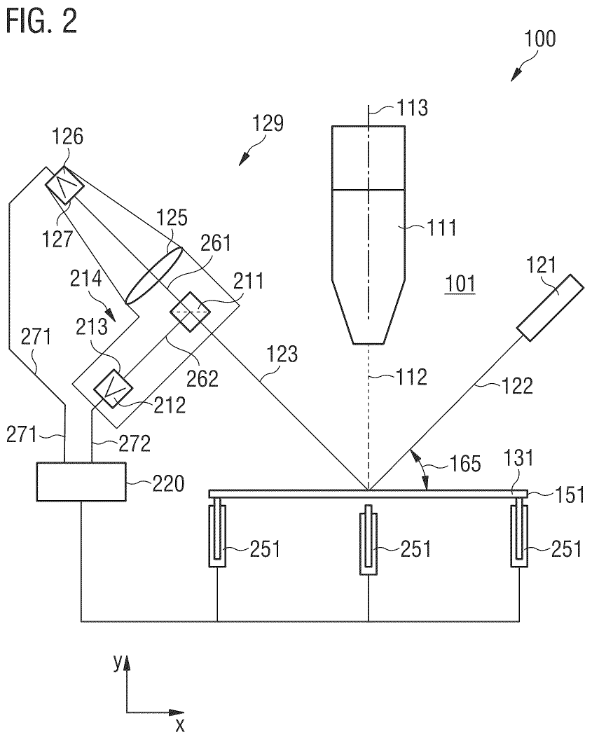

It might sometimes be desirable to quantify the arrangement of the sample not only in respect of its tilt 109 but also in respect of its height. A corresponding modification of the microscope system 100 is shown in FIG. 2.

FIG. 2 schematically illustrates the particle microscope system 100 according to a variation. A further detector system 214 is also provided in addition to the autocollimator detector system 129. By combining the detector systems 129, 214 it is possible to measure both the height of the sample and the tilt 109.

A beam splitter 211 which splits the beam path 123 of the laser light into two parts 261, 262 is integrated in FIG. 2. The part 261 is then guided to the autocollimator detector system 129, i.e. to the focusing lens 125 and the sensor 126 (already described in the context of FIG. 1). The part 262 is steered to the sensor surface 213 of a multi-pixel sensor 212 of the detector system 214. No focusing lens is used. A signal 272 sensitive both to the tilt of the surface of the sample (e.g. wafer 131) and to the height 108 of the sample is obtained thereby.

The height 108 of the sample can once again be defined in the reference coordinate system. If the XY-plane of the spherical coordinate reference coordinate system extends on the holding surface 152 of the sample stage 151 in the zero position, then the height 108 can be defined as the distance of the sample from the XY-plane.

A data processing unit 220 which quantifies both the height and, separately therefrom, the tilt of the reflector on the basis of the signal 271 and on the basis of the signal 272 can be provided.

For example, the tilt of the reflector in the beam path can initially be determined only on the basis of the signal 271 in a first step. Then, with knowledge of the tilt of the reflector, the height of the reflector can be determined on the basis of the signal 272. Iterative methods which successively search for a convergence of the values for the height and the tilt on the basis of the corresponding formulas would also be conceivable.

While the example in FIG. 2 shows coupling of the output of the data processing device 220 with actuators 251 (for example piezo actuators) of the sample holder 151, the presence of such coupling is not required in all variants. If such coupling is present, as shown in FIG. 2, the sample holder 151 can be repositioned accordingly on the basis of the measured tilt 109 and/or height 108. For example, the sample holder 151 could be positioned by driving the actuators 251 such that the wafer 131 extends in the XY-plane of the spherical reference coordinate system.

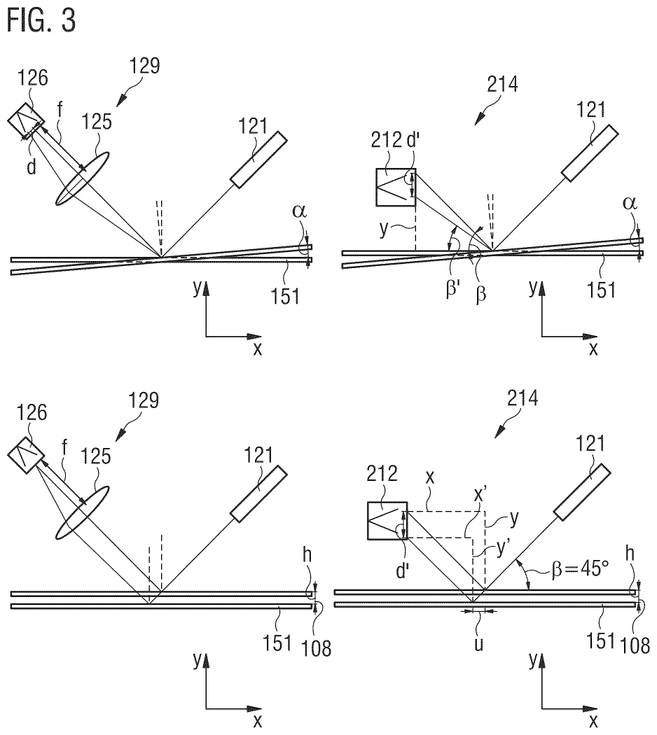

The measurement principle of the autocollimator detector system 129 and detector system 214 is illustrated further in FIG. 3. FIG. 3 in each case shows the change in the position of the light spot on the respective sensor 126, 212 for a change in the tilt 109 (top) and a change in the height 108 (bottom).

The displacement d′ of the light spot on the sensor surface 213 of the sensor 212 on account of the tilt 109 is given by d′=x·tan β−x·tan β′. The angles β, β′ are dependent on the tilt a. The displacement on account of a variation in height 108 is given by d″=2h. This means that the displacement on the sensor 212 is influenced by the tilt and the change in height. However, height and tilt can be calculated separately by considering both signals 271, 272.

By considering the signal 271—which is only sensitive to the tilt 109—it is possible to correct the tilt in the signal 272 by calculation. For example, it is possible to initially calculate what the tilt determined from signal 271 would mean for the signal 272. If the corrected value still exhibits a deviation from the original output signal/zero position, then this deviation—i.e. d″—is to be caused by a height variation which can be determined using the formula given. Thus this is a two-stage calculation in order to initially quantify the tilt and then the height.

To assess the sensitivities, the signal displacements on both sensors 126, 212 caused by a change in the tilt 109 or by a change in the height 108 are considered by way of example hereinbelow. The system parameters listed are examples and may vary depending on the specific realization.

If a focal length f=250 mm is chosen for the focusing lens 125, then a wafer surface angular change of 50 prad (change in the tilt 109) causes a laser signal displacement of 25 μm on the sensor surface 127. Industrial CMOS cameras—as an example for the sensor 126—with a conventional pixel pitch of 3.45 μm can easily detect this displacement. Under this angular change, the sensor 212 indicates a displacement of the signal by 60 μm for a distance x=300 mm and an angle of incidence 165 of β=45°; this can also be detected via the CMOS camera. In view of the aforementioned pixel pitch, this means that angular changes of <10 μrad are easily measurable Moreover, the sensitivity can be increased further by adapting the focal length of the focusing lens 125. Table 1 summarizes the aforementioned values.

TABLE 1
Tilt sensitivity (at constant height) In this case,
the angle of incidence 165 is defined in relation
to a zero position of the sample holder 151.

| Autocollimator detection system 129 | | Detection system 214 | |
|---|---|---|---|
| d = tan α · 2f | | d′ = x · tan β − x · tan β′ | |
| Tilt | α = 50 · 10⁻⁶ rad | First tilt angle of | β = 45° |
| | | incidence | |
| Lens 125 focal | f = 25 cm | Second tilt angle of | β′ = 44.99° |
| length | | incidence | |
| | | Lateral offset | x = 300 mm |
| Signal | d = 25 μm | Signal | d = 60 μm |

Table 2 shows the sensitivities of this arrangement in the case of a height variation of 10 μm. When the height varies, the sensor 125 does not indicate a signal change on account of the autocollimation, but the sensor 212 detects a signal change. In the example considered here, 10 μm height variation causes a signal displacement of 20 μm on the sensor plane and is therefore clearly detectable on the camera.

TABLE 2
Height sensitivity (at constant tilt)

| Autocollimator detection system 129 | | Detection system 214 | |
|---|---|---|---|
| d = tan α · 2f | | d″ = 2h | |
| Tilt | α = 0 rad | Height variation | h = 0.01 mm |
| Lens 125 focal | f = 25 cm | Angle of incidence | β = 45° |
| length | | | |
| Signal | d = 0 μm | Signal | d″ = 20 μm |

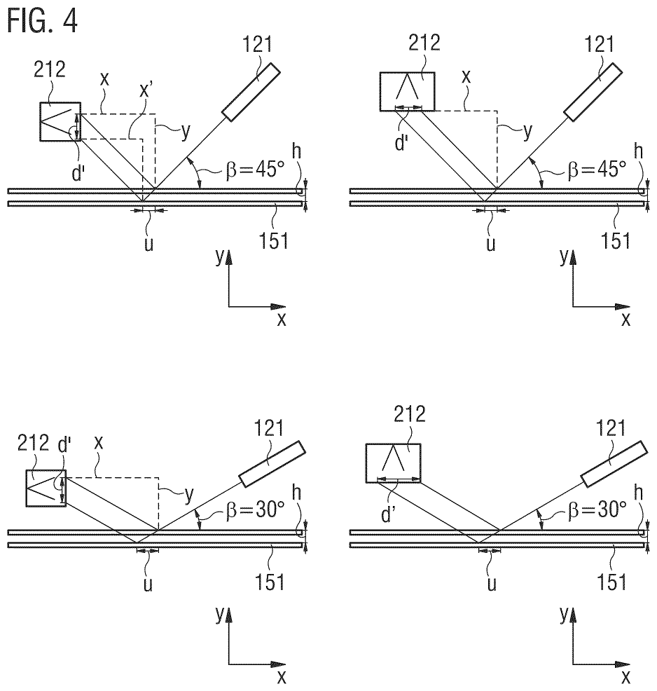

In this case, too, the sensitivity can be increased further or adapted to the measurement task. FIG. 4 schematically illustrates an alternative arrangement of the sensor 212. While the signal shift d″ caused by a height variation h is independent of the angle of incidence β in the arrangement shown previously (on the left in FIG. 4), β influences the signal displacement on the sensor in the alternative arrangement (on the right in FIG. 4).

As illustrated in Table 3, the sensitivity is increased by reducing the angle of incidence p from 45° to 30°, and so a change in height of 10 μm increases the signal displacement from 20 μm (according to the arrangement on the left) to 34.6 μm (according to the arrangement on the right).

TABLE 3
Height sensitivity for various arrangements of the sensor in the
further detector system. The first option (left-hand column) does
not exhibit any sensitivity to the angle of incidence; by contrast,
a sensitivity to the angle of incidence is present in the second
arrangement - right-hand column. In general, it was established
that good results can be obtained for an angle of incidence in
the range of 10° or 15° to 50° or 45°. This statement
once again relates to a zero position of the sample holder 151;
i.e. the holding surface 152 of the sample holder 141 is parallel
to an XY-plane of the spherical reference coordinate system in
this case. This means that a surface normal of the holding surface
152 is parallel to the central axis 113 of the source column 111
of the SEM arranged at a polar angle of 90°.

| | | Alternative arrangement of detection | |
|---|---|---|---|
| Detection system 214 | | system 214 | |
| d″ = 2 · h | | d″ = 2 · u | |
| Height variation | h = 0.01 mm | Height variation | h = 0.01 mm |
| Angle of incidence | β = 30° | Angle of incidence | β = 30° |
| | | Offset | u = 17.32 μm |
| Signal | d″ = 20 μm | Signal | d″ = 34.64 μm |

The examples shown firstly illustrate the very high measurement accuracy of the method, in that angular changes <10 μrad and height variations of a few micrometres are easily measurable, and the great flexibility of the method. The sensitivity of the measurement structure can be optimally designed for the respective application by appropriately designing the system parameters such as focal length, pixel pitch and geometric arrangement.

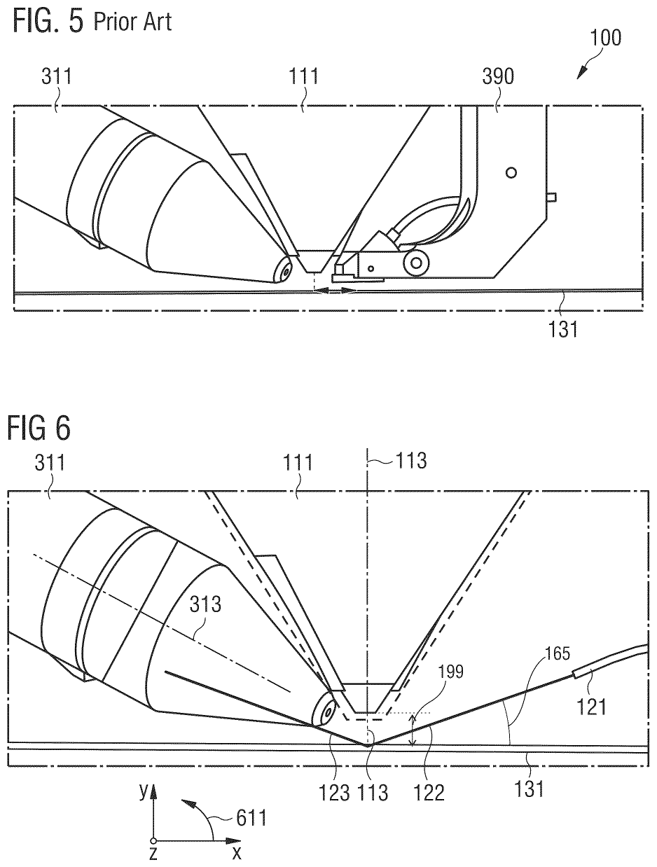

Using the techniques described above, it is possible to measure the tilt 109 and optionally also the height 108 of the sample in the measurement region directly below the SEM source column 111. This is made possible by the oblique incidence of the laser light with the relatively flat angle of incidence 165 of the beam path 122 at the sample holder 151 (in the zero position in any case). A scenario according to the prior art is illustrated by comparison in FIG. 5. Shown there is a capacitive height sensor 390 which is arranged at a distance (double-headed arrow) from the scanning region of the SEM (the SEM column 111 is illustrated). In the example of FIG. 5, the particle microscope system 100 also still comprises a further source column 311, for example an FIB column. Even for such a scenario with an FIB source column 311 in crossed arrangement with the SEM source column 111, it is possible to guide the beam path 122, 123 to a measurement region arranged directly below the SEM source column 111 so that the central axis 113 intersects the measurement region. This is shown in FIG. 6. In this case, the SEM source column 111 blocks a region above the measurement region (this region is delimited by the dashed lines), and so the angle of incidence 165 is chosen to be less than 56°. In this case, the angle of incidence 165 corresponds to a polar angle 611 in a polar coordinate system with an XY-plane located on the holding surface 152 in the zero position. In that case, the central axis 113 of the SEM source column 111 is at a polar angle 611 of 90°; at the same time, the central axis 313 of the FIB source column 311 is located at a polar angle 611 of approximately 144° to 155° (this corresponds to a tilt out of the plane of the holding surface 152 in the zero position of 25° to 36°).

The working distance (WD) 199 of the electron microscope is defined as the distance between SEM objective and sample surface. The working distance 199 is usually chosen between 1 mm and 5 mm. As a result of the relatively small working distance 199, the accessibility to the region on the sample surface below the SEM objective, i.e. the scan region, is greatly restricted for the beam path 122, 123. Nevertheless, a measurement can be carried out directly at the position of the electron beam as a result of the oblique incidence of the laser light.

However, at the same time, the range over which the working distance 199 can be varied and a measurement of the tilt and/or height can be performed at the same time is limited: If the working distance 199 is modified too much, then beam path 123 will no longer be reflected at the detector. The reflected laser beam would be located outside of the acceptance range of the sensors. Hence, a fixed working distance can be set when performing a measurement with the detection systems for the purpose of measuring the height and/or the tilt. The sample holder can be driven in an appropriate measurement mode in order to adopt this working distance.

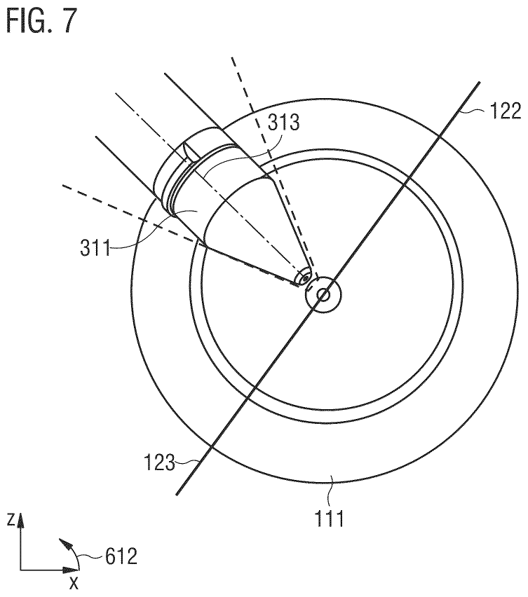

FIG. 7 shows the corresponding arrangement of the beam path 122, 123 and the central axis 113 in relation to an azimuth angle 612. It is evident from FIG. 7 that the beam path 122, 123 is approximately perpendicular to the central axis 313 of the FIB source column 311 in the plane of the drawing of FIG. 7 (which is parallel to the xy-plane of the spherical reference coordinate system); i.e. the azimuth angle 612 of the central axis 313 differs from an azimuth angle of the beam path 122, 123 by approximately 90°. For example, the region inaccessible to the guidance of the beam path 122, 123 on account of the FIB source column 311 is emphasized in FIG. 7 using dashed lines. In general, the azimuth angle 612 of the central axis 313 can differ from the azimuth angle of the beam path 122, 123 by 80° to 100°.

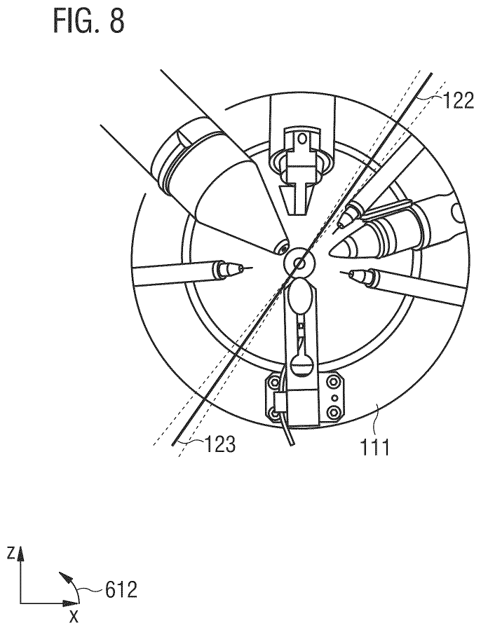

The installation space in the immediate vicinity of the scan region is limited, especially in the case of FIB-SEM applications, since further equipment (e.g. precursor gas sources or micromanipulators or detectors) should be placed as close to the sample as possible in that case. This is shown in FIG. 8. The method is suitable for realizing, within this limited installation space, the measurement technology used to this end. The azimuthal arrangement for example is much restricted in this case as a result of the aforementioned additional component parts. An angular range (between the dashed lines) of approximately 10° is available for the beam path 122, 123. This is sufficient for guiding the laser light to the reflector and input coupling it from there into the described sensors.

On account of the comparatively small beam cross section of the beam path 192, 123, the optical measurement can also be integrated in such a limited installation space as shown in FIG. 8. The laser light source 121 and the detector systems 129, 214 can be arranged at a sufficient distance from a point of intersection of the central axis 113 with the sample holder 151 (origin of the spherical coordinate system). Electromagnetic interference is prevented.

It goes without saying that the features of the embodiments and aspects of the invention described above can be combined with one another. For example, the features can be used not only in the combinations described but also in other combinations or on their own, without departing from the scope of the invention.

What is claimed is:

1. A particle microscope system, comprising:
a vacuum chamber;
a sample holder comprising a holding surface extending in a plane of the vacuum chamber;
a first source column in the vacuum chamber, the first source column configured to shape and scan a first primary particle beam;
a laser light source configured to emit laser light towards the holding surface along a beam path; and
a first detection system in the beam path downstream of the holding surface in a propagation direction of the laser light, the first detection system configured to output a signal which is selectively sensitive to a tilt of a reflector in the beam path at the holding surface,
wherein a projection of the beam path on the holding surface defines a measurement region, and a central axis of the first source column intersects the measurement region.

2. The particle microscope system of claim 1, further comprising:
a beam splitter in the beam path downstream of the holding surface in the propagation direction of the laser light, the beam splitter configured to split the beam path into a first part and a second part, the first detection system being in the first part of the beam path; and
a second detection system, the second detection system being in the second part of the beam path, the second detection system configured to output a signal which is sensitive to both the tilt of the reflector and a height of the reflector.

3. The particle microscope system of claim 2, further comprising a data processing device configured to quantify the tilt of the reflector based on: i) the signal from the first detection system; and ii) the signal from the second detection system, wherein the data processing device is also configured to quantify the height of the reflector.

4. The particle microscope system of claim 3, wherein the second detection system comprises a sensor surface of a multi-pixel sensor, and the sensor surface is configured so that a sensitivity of a measurement of the height depends on an angle of incidence of the beam path with respect to the holding surface.

5. The particle microscope system of claim 2, wherein the second detection system comprises a sensor surface of a multi-pixel sensor, and the sensor surface is configured so that a sensitivity of a measurement of the height depends on an angle of incidence of the beam path with respect to the holding surface.

6. The particle microscope system of claim 2, wherein the first detection system comprises an autocollimator detection system, and the second detection system comprises an optical detection system.

7. The particle microscope system of claim 1, further comprising a second source column disposed in the vacuum chamber, wherein the second source column is configured to shape a second primary particle beam and emit the second primary particle beam towards the holding surface, and wherein the first and second source columns have a crossed arrangement.

8. The particle microscope system of claim 7, wherein:
the central axis of the first source column is at a polar angle of 90° with respect to the holding surface;
a central axis of the second source column is at a polar angle of more than 100° with respect to the holding surface; and
the beam path upstream of the reflector is at a polar angle of at most 60° with respect to the holding surface.

9. The particle microscope system of claim 8, wherein an azimuth angle of the central axis of the second source column differs by 80°-100° from an azimuth angle of the beam path.

10. The particle microscope system of claim 1, wherein the first detection system is configured to focus the laser light on a multi-pixel sensor of the first detection system so that a position of a light spot on a sensor surface of the multi-pixel sensor changes with the tilt of the reflector.

11. The particle microscope system of claim 1, wherein the beam path makes an angle of 15° to 50° with respect to the holding surface of the sample holder.

12. The particle microscope system of claim 1, wherein an acceptance angle of the first detection system is at most +/−3°.

13. The particle microscope system of claim 1, further comprising a data processing unit configured to receive the signal from the first detection system after the sample holder has been brought to a predefined working distance from the source column.

14. The particle microscope system of claim 1, wherein the first detection system comprises an autocollimator detection system.

15. A method, comprising:
using the particle microscope system of claim 1 to determine the arrangement of the sample.

16. A method of using a particle microscope system, the particle microscope system comprising a sample on a holding surface of a sample holder of the particle microscope system, the sample holder positioned in a vacuum chamber of the particle microscope system so that the sample is below a source column of the particle microscope system, the method comprising:
directing laser light towards a holding surface along a beam path so that the laser light is reflected at the sample below the microscope objective; and
controlling an autocollimator detection system in the beam path downstream of the sample in the propagation direction of the laser light to obtain a signal which is selectively sensitive to a tilt of the sample.

17. The method of claim 16, further comprising controlling a further detection system in the beam path downstream of the sample in the propagation direction of the laser light to obtain a further signal which is sensitive to both the tilt of the sample and a height of the sample.

18. The method of claim 17, further comprising:
quantifying the tilt of the sample based of the signal from the autocollimator detection system; and
quantifying the height of the sample based on the signal from the autocollimator detection system and the signal from the further detection system.

19. The method of claim 18, wherein the height of the sample is quantified based on the quantified tilt of the sample.

20. The method of claim 16, wherein the sample comprises a wafer having a diameter of at least 100 mm.
